(19) United States
(12) Patent Application Publication
(10) Pub. No.: US 2007/0209686 A1
(43) Pub. Date: Sep. 13, 2007

(54) APPARATUS FOR CLEANING CHAMBER USING GAS SEPARATION TYPE SHOWERHEAD

(75) Inventors: Guen Hag BAE, Kyungki-do (KR); Kyung Soo KIM, Seoul (KR); Ho Sik KIM, Kyungki-do (KR); Young Bea YUN, Ulsan-si (KR); Duck Jin KIM, Busan-si (KR); Nae Eung LEE, Kyungki-do (KR)

Correspondence Address: CANTOR COLBURN, LLP, 55 GRIFFIN ROAD SOUTH, BLOOMFIELD, CT, 06002, US

(73) Assignee: ATTO CO., LTD., Kyungki-do (KR)

(21) Appl. No.: 11/683,108

(22) Filed: Mar. 7, 2007

(30) Foreign Application Priority Data
Mar. 7, 2006 (KR) 10-2006-0021300
May 24, 2006 (KR) 10-2006-0046602
Jul. 18, 2006 (KR) 10-2006-0066983

(51) Int. Cl. B08B 3/00; C23F 1/00; C23C 16/00

(52) U.S. Cl. 134/94.1; 118/715; 156/345.34

(57) ABSTRACT

An apparatus for cleaning an inside of a chamber using a gas separation type showerhead is provided. The apparatus includes: a gas supply module through which first and second gases are separately supplied; a gas separation module through which the first and second gases are separately dispersed; and a gas injection module that includes a plurality of holes through which the separately dispersed first and second gases are commonly injected into the chamber, wherein at least one gas of the first and second gases includes an ionized first cleaning gas including a gas containing fluorine (F) ingredient, and wherein at least one gas of the first and second gases includes a non-ionized second cleaning gas including nitrogen oxide based gas (NxOy, x and y are integers equal to or more than 1).

### BACKGROUND OF THE INVENTION

1. Field of the Invention

The present invention relates to an apparatus for cleaning a chamber, and more particularly, to an apparatus for cleaning a chamber using a gas separation type showerhead in which a cleaning gas including ionized fluorine (F) ingredient and a non-ionized nitrogen oxide based cleaning gas are used as a cleaning gas.

2. Description of the Related Art

In a conventional method of cleaning a chamber, a cleaning gas flows from the top to the bottom of the chamber due to structures of a top-down showerhead and the chamber. Accordingly, as efficiency of cleaning upper part of the chamber decreases, the total time for cleaning the chamber increases. In addition, since much cleaning gas is used, productivity decreases.

For example, in order to clean an inside of a CVD chamber, perfluorized compound based cleaning gas (hereinafter, referred to as PFC) such as CF₄, C₂F₆, C₃F₈, C₄F₈, and SF₆ is supplied to the CVD chamber together with oxygen gas (O₂) or argon gas (Ar). The inside of the CVD chamber is cleaned by applying RF plasma to the CVD chamber. However, when the PFC based cleaning gas is used, there are problems such as damage of internal parts of the chamber, global warming, a low cleaning speed, and environmental problems.

In order to solve the aforementioned problems, the inside of the CVD chamber is cleaned by ionizing nitrogen trifluoride (NF₃) cleaning gas through a remote plasma generator and supplying the ionized nitrogen trifluoride (NF₃) cleaning gas together with argon gas (Ar) to the chamber instead of the PFC based cleaning gas. When the nitrogen trifluoride (NF₃) cleaning gas is used, the direct damage of the internal parts of the chamber decreases, and the cleaning speed increase. However, there remain environmental problems such as global warming. Production costs increase by using a high price gas.

In order to improve efficiency of cleaning a chamber using fluorine (F₂) cleaning gas, nitrogen gas (N₂) or nitrogen oxide based gas (NxOy) such as nitric oxide (NO), nitrogen dioxide (N₂O), and the like is recently supplied to the chamber together with the fluorine (F₂) cleaning gas through the remote plasma generator.

FIG. 1 illustrates a conventional apparatus 100 for cleaning a chamber using fluorine (F₂) cleaning gas and nitrogen oxide based cleaning gas (NxOy).

Referring to FIG. 1, fluorine (F₂) cleaning gas 110a and nitrogen oxide based cleaning gas 110c are ionized together with argon gas (Ar), which is an additive gas, through a remote plasma source 120. An ionized mixed cleaning gas is supplied to a top-down showerhead 130 and injected into a chamber 140 through the showerhead 130.

However, in the aforementioned method, there is a limit in improving the cleaning efficiency by adding the additive gas, since the nitric oxide gas (NO), which most influences the cleaning efficiency except a gas containing fluorine ingredient (F), is supplied as forms of not NO radicals but nitrogen (N) or oxygen (O) radicals into the chamber.

### SUMMARY OF THE INVENTION

The present invention provides an apparatus for cleaning a chamber using a gas separation type showerhead capable of improving efficiency of cleaning an inside of the chamber by supplying a cleaning gas including fluorine (F) ingredient in ionized state to the gas separation showerhead and supplying a cleaning gas including nitrogen oxide based ingredient in non-ionized state to the gas separation type showerhead.

The present invention also provides an apparatus for cleaning a chamber using a gas separation type showerhead capable of effectively cleaning an upper part of an inside of the chamber through a separate gas injection module in a side direction out of the gas separation type showerhead.

According to an aspect of the present invention, there is provided an apparatus for cleaning an inside of a chamber using a gas separation type showerhead, the apparatus comprising: a gas supply module through which first and second gases are separately supplied; a gas separation module through which the first and second gases are separately dispersed; and a gas injection module that includes a plurality of holes through which the separately dispersed first and second gases are commonly injected into the chamber, wherein at least one gas of the first and second gases includes an ionized first cleaning gas including a gas containing fluorine (F) ingredient, and wherein at least one gas of the first and second gases includes a non-ionized second cleaning gas including nitrogen oxide based gas (NxOy, x and y are integers equal to or more than 1).

According to another aspect of the present invention, there is provided an apparatus for cleaning an inside of a chamber using a gas separation type showerhead, the apparatus comprising: a gas separation type showerhead including a gas supply module through which first and second gases are separately supplied, a gas separation module through which the supplied first and second gases are separately dispersed, and a gas injection module including a plurality of holes, in which the separately dispersed first and second gases are commonly injected through the plurality of holes; a third gas supply module surrounding an outer surface of the gas separation type showerhead, through which a third gas for cleaning the inside of the chamber is supplied and transported; and a third gas injection module through which the supplied third gas is injected into the chamber.

According to another aspect of the present invention, there is provided an apparatus for cleaning an inside of a chamber using a gas separation type showerhead, the apparatus comprising: a gas separation type showerhead including a gas supply module through which first and second gases are separately supplied, a gas separation module through which the supplied first and second gases are separately dispersed, and a gas injection module including a plurality of holes, in which the separately dispersed first and second gases are commonly injected through the plurality of holes; a third gas supply module surrounding an outer surface of the gas separation type showerhead, through which a third gas for cleaning the inside of the chamber is supplied and transported; and a third gas injection module through which the supplied third gas is injected into the chamber, wherein at least one gas of the first and second gases and the third gas are gases for cleaning the inside of the chamber.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a conventional apparatus for cleaning a chamber;

FIG. 2 illustrates an example of a gas separation type showerhead used for the present invention;

FIG. 3 illustrates a three-dimensional cross section of a gas separation module and a gas injection module of the gas separation type showerhead shown in FIG. 2;

FIGS. 4 to 6 illustrate examples of a system for supplying a cleaning gas used for the present invention;

FIGS. 7 and 8 illustrate an injection shape of a cleaning gas injected from the gas separation type showerhead shown in FIG. 2;

FIG. 9 illustrates another example of a system of supplying a cleaning gas used for the present invention;

FIGS. 10 and 11 illustrate injection shapes of a mixed cleaning gas and a gas for preventing back flow injected from the gas separation type showerhead shown in FIG. 2;

FIG. 12 illustrates another example of a gas separation type showerhead used for the present invention;

FIGS. 13 to 15 are bottom plan views of a third gas injection module of the gas separation type showerhead shown in FIG. 12;

FIGS. 16 and 17 are side views of the third gas injection module of the gas separation type showerhead shown in FIG. 12; and

FIGS. 18 to 22 illustrate injection shapes of gases injected from the gas separation type showerhead shown in FIG. 12.

### DETAILED DESCRIPTION OF THE INVENTION

Now, preferred embodiments of the present invention will be described in detail with reference to the attached drawings.

In the present invention, a gas separation type showerhead is basically used.

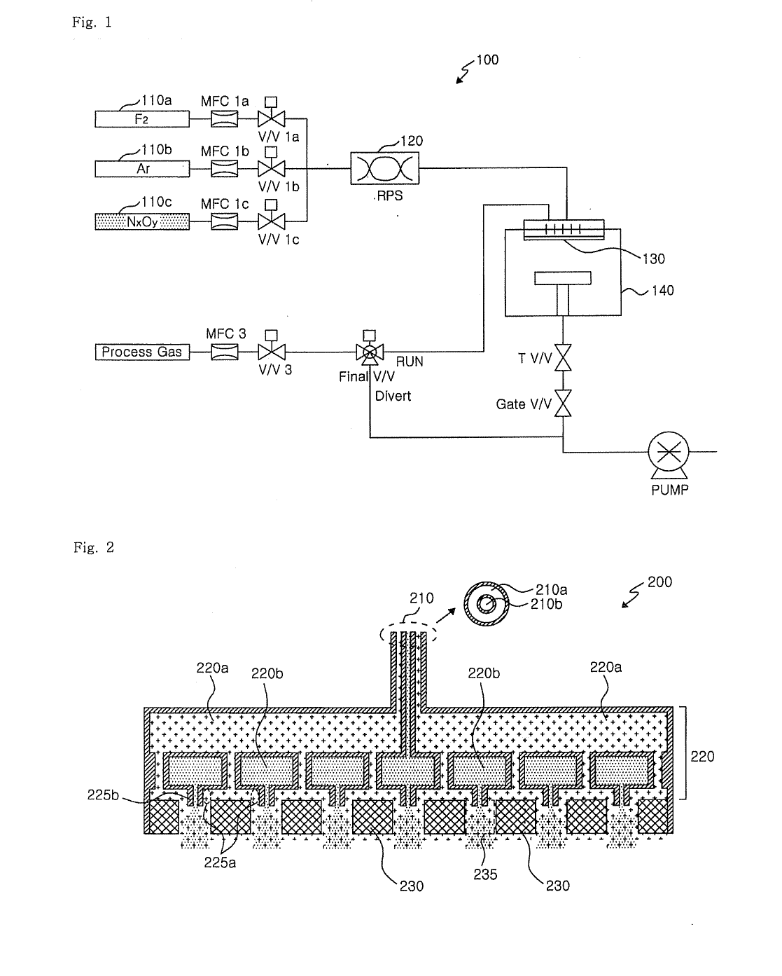

FIG. 2 illustrates an example of a gas separation type showerhead used for the present invention. A gas separation type showerhead 200 shown in FIG. 2 includes a gas supply module 210, a gas separation module 220, and a gas injection module 230.

First and second gases A and B are separately supplied through the gas supply module 210. In order to separately supply the first and second gases A and B, the gas supply module 210 includes outer and inner supply tubes 210a and 210b which are separated from each other. Referring to FIG. 2, the second gas A is supplied to the outer supply tube 210a, and the second gas B is supplied to the inner supply tube 210b.

The first and second gases A and B supplied from the gas supply module 210 are separately dispersed through the gas separation module 220. In order to separately disperse the first and second gases A and B, a first dispersion region 220a is connected to the outer supply tube 210a of the gas supply module 210, and a second dispersion region 220b is connected to the inner supply tube 210b of the gas supply module 110. Referring to FIG. 2, the first gas A is dispersed in the first dispersion region 220a, and the second gas B is dispersed in the second dispersion region 220b.

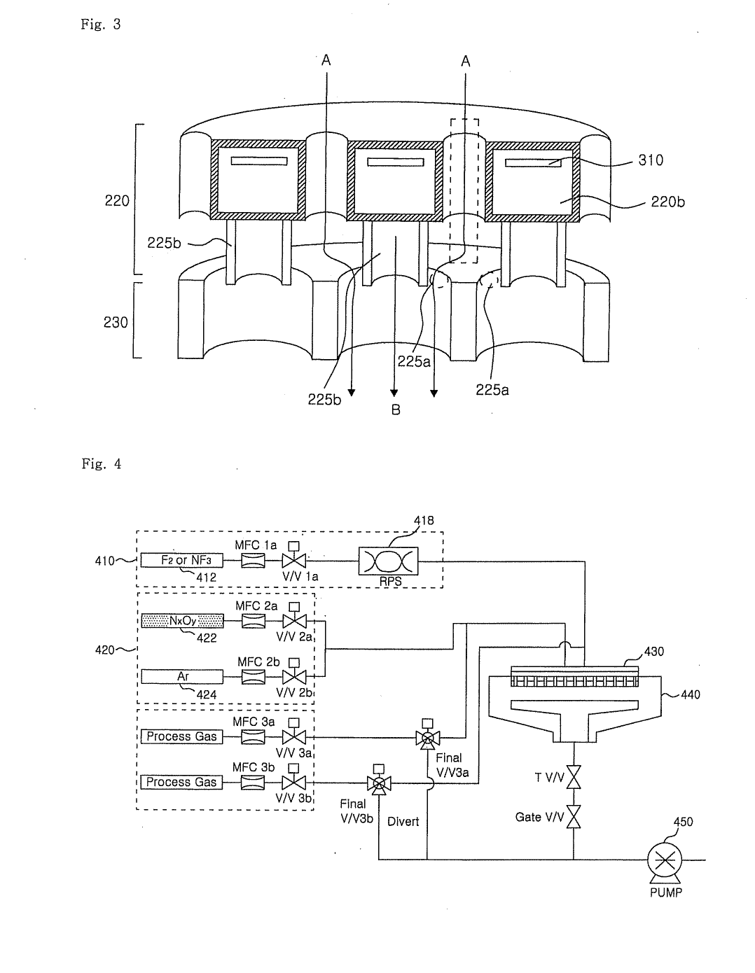

The first dispersion region 220a is constructed with one region. The second dispersion region 220b is located under the first dispersion region 220a and divided into a plurality of regions. Preferably, a gas distribution plate (310 of FIG. 3) may be provided to uniformly disperse the second gas B in the divided regions of the second dispersion region 220b.

Neighboring divided regions of the second dispersion region 220b are spaced apart from each other, that is, a constant space exist between the outer surfaces of the neighboring divided regions. Further, a vent 225b is formed at the lower part of each of the regions of the second dispersion region 220b.

The gas injection module 230 includes a plurality of holes 235. The first and second gases A and B, which are separately dispersed from the gas separation module 220, are commonly injected into the chamber through the plurality of holes 235. Surely, the first and second gases A and B may be simultaneously or sequentially injected into the chamber.

FIG. 3 illustrates a three-dimensional cross section of a gas separation module 220 and a gas injection module 230 of the gas separation type showerhead 200 shown in FIG. 2.

Referring to FIG. 3, the second gas B is vented to the gas injection module 230 through the plurality of vents 225b. The first gas A is vented to the gas injection module 230 from the first dispersion region 220a through the outer spaces of the second dispersion region 220b and spaces 225a surrounding the vents 225b.

FIGS. 4 to 6 illustrate examples of a system for supplying a cleaning gas used for the present invention.

The cleaning gas used for the present invention includes two types of cleaning gases. A cleaning gas indicates a first cleaning gas including ionized fluorine (F) ingredient. The other cleaning gas indicates a second cleaning gas containing non-ionized nitrogen oxide based ingredient (NxOy, x and y are integers equal to or more than 1).

The first cleaning gas is supplied through a first cleaning gas supply line 410, and the second cleaning gas is supplied through a second cleaning gas supply line 420.

The first cleaning gas supply line 410 includes a fluorine (F) source 412 and a remote plasma source (RPS) 418 for ionizing the first cleaning gas so as to supply the first cleaning gas including a gas containing a fluorine (F) ingredient such as fluorine (F₂) and nitrogen trifluoride (NF₃) in ionized state.

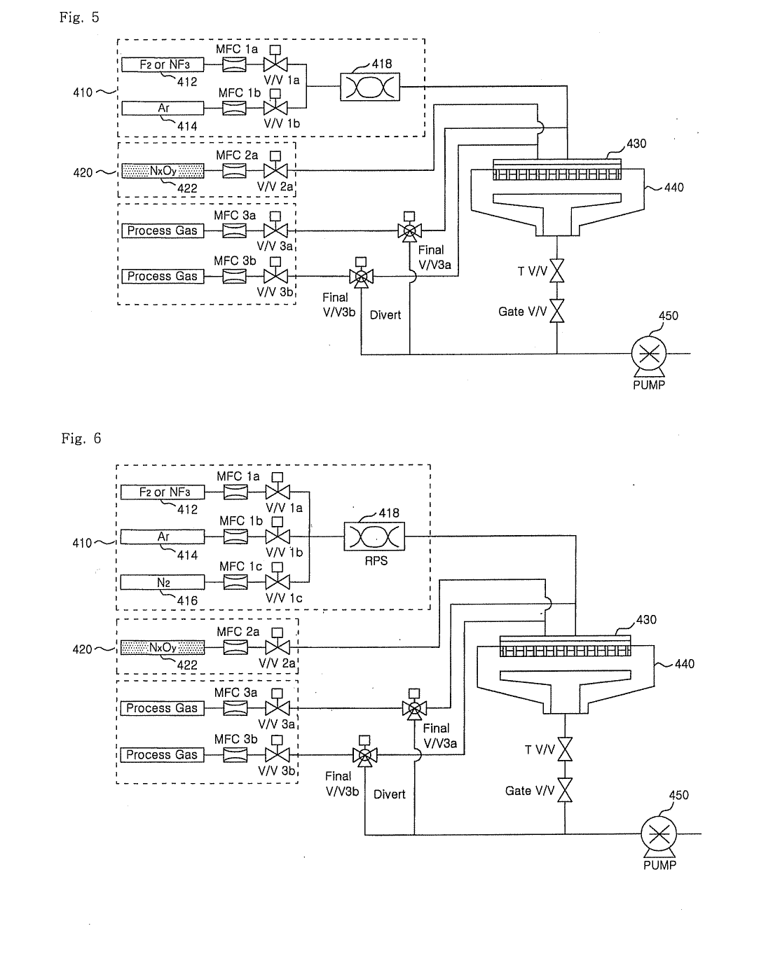

In the example shown in FIG. 4, the first cleaning gas is pure fluorine gas or pure nitrogen trifluoride gas. In the example shown in FIG. 5, the first cleaning gas is a mixture of argon gas (Ar) and fluorine gas (F₂) or a mixture of argon gas (Ar) and nitrogen trifluoride (NF₃) gas. In the example shown in FIG. 6, the first cleaning gas is a mixture of argon gas (Ar), nitrogen gas (N₂), and fluorine gas (F₂).

It is generally known that cleaning efficiency of the inside of the chamber is proportional to the concentration of fluorine (F) ingredient included in the cleaning gas. Accordingly, the cleaning efficiency can be maximized by increasing the concentration of fluorine gas (F₂) and nitrogen trifluoride gas (NF₃) to the highest degree. For this, like the example shown in FIG. 4, pure fluorine gas (F₂) or pure nitrogen trifluoride gas (NF₃) may be used. However, in order to use pure fluorine gas (F₂) or pure nitrogen trifluoride gas (NF₃), there is required a cleaning apparatus which can sufficiently resist corrosivity of fluorine gas (F₂) or nitrogen trifluoride gas (NF₃). Therefore, the price of the cleaning apparatus may increase. Accordingly, as in the example shown in FIG. 5, the mixture of argon gas (Ar) and fluorine gas (F₂), or the mixture of argon gas (Ar) and nitrogen trifluoride (NF₃) may be used. When the mixture of argon gas (Ar) and fluorine gas (F₂) is used, the cleaning efficiency may decrease. Therefore, in order to improve the cleaning efficiency by adding nitrogen gas (N₂) to the mixture of argon gas (Ar) and fluorine gas (F₂), as shown in FIG. 6, the mixture of argon gas (Ar), nitrogen gas (N₂), and fluorine gas (F₂) may be used as the first cleaning gas.

Referring to FIG. 5, the argon gas (Ar) is supplied from the argon (Ar) source 414 and mixed with the fluorine gas (F₂) or nitrogen trifluoride gas (NF₃) before being supplied to the RPS 418. Referring to FIG. 6, the argon gas (Ar) and the nitrogen gas (N₂) are respectively supplied from the argon (Ar) and nitrogen (N₂) sources 414 and 416 and mixed with the fluorine gas (F₂) or nitrogen trifluoride gas (NF₃) before being supplied to the RPS 418.

In FIGS. 5 and 6, the argon gas (Ar) supplied from the argon (Ar) source 414 serves to dilute the fluorine gas (F₂) or nitrogen trifluoride gas (NF₃). In addition, the argon gas (Ar) is firstly supplied to the RPS 418. The argon gas (Ar) may operate as a plasma ignition gas of the RPS 418.

The second cleaning gas supply line 420 includes nitrogen oxide based gas (NxOy) source 422 so as to supply the second cleaning gas including the nitrogen oxide based gas.

The second cleaning gas includes nitrogen oxide based gas (NxOy) such as NO, NO₂, N₂O, and the like, which has a specific ratio of nitrogen (N) to oxygen (O) (x and y are integers equal to or more than 1).

The cleaning efficiency is improved by the non-ionized nitrogen oxide based gas (NxOy) as described in the following. Silicon ingredient, which is contained in a solid film such as an oxide film and a nitride film deposited on the wall of the chamber during a deposition process, is combined with fluorine (F) radicals. Then, oxygen (O) or nitrogen (N) ingredient which remains in the solid film is excited by the radicals containing fluorine (F) ingredient. Then, the excited oxygen or nitrogen (N) ingredient easily reacts against the nitrogen oxide based gas (NxOy) which is directly supplied without passing through the RPS.

In the example shown in FIGS. 5 and 6, the second cleaning gas is pure nitrogen oxide based gas NxOy. In the example, shown in FIG. 4, the second cleaning gas is a mixture of argon gas (Ar) and nitrogen oxide based gas (NxOy).

Referring to FIG. 4, the argon gas (Ar) is supplied from the argon (Ar) source 424 and mixed with the nitrogen oxide based gas (NxOy).

Referring to FIGS. 4 to 6, a mass flow controller MFC and a valve V/V are sequentially connected to each of the gas sources 412, 414, 416, 422, and 424 for generating the first and second cleaning gases. The connection is similarly applied to a case of a process gas. A chamber 440 is connected to an exhaust pump 450 for exhausting the chamber of remaining gas including the cleaning gas after the inside of the chamber is cleaned.

That is, referring to FIGS. 4 to 6, the ionized first cleaning gas may be one of i) pure fluorine gas (F₂), ii) a mixture of argon gas (Ar) and fluorine gas (F₂), iii) a mixture of argon gas, nitrogen gas (N₂), and fluorine gas (F₂), iv) pure nitrogen trifluoride gas (NF₃), and v) a mixture of argon gas (Ar) and nitrogen trifluoride gas (NF₃). The non-ionized second cleaning gas may be one of i) pure nitrogen oxide based gas and ii) a mixture of argon gas (Ar) and nitrogen oxide based gas (NxOy).

In FIGS. 4 to 6, the showerhead 430 may employ the gas separation type showerhead 200 shown in FIG. 2.

For example, the first and second cleaning gas supply lines 410 and 420 may be respectively connected to the outer and inner supply tubes 210a and 210b.

Accordingly, in the example, an ionized first cleaning gas is supplied to the outer supply tube 210a of the gas supply module 210, and a non-ionized second cleaning gas is directly supplied to the inner supply tube 210b of the gas supply module 210. The supplied first and second cleaning gases are respectively dispersed from the first and second dispersion regions 220a and 220b of the gas separation module 220, mixed with each other through the plurality of holes 235 in the gas injection module 230, and injected into the chamber 440.

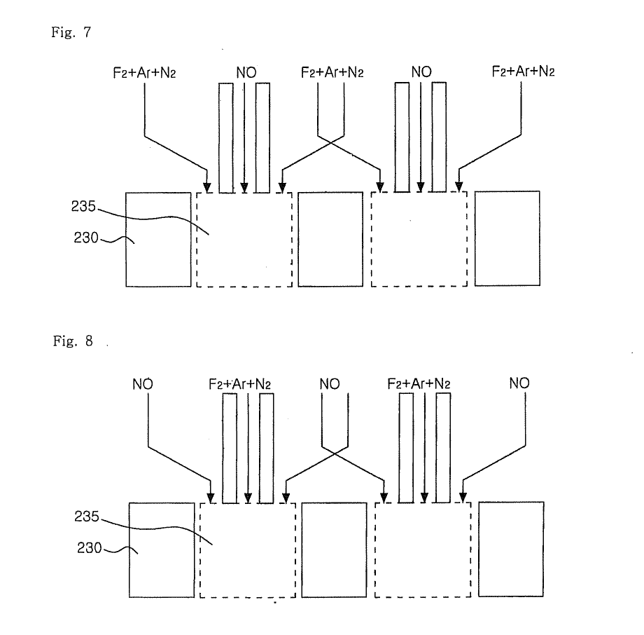

In FIG. 7, the gas supplied to the outer supply tube 210a of the gas supply module 210 is the first cleaning gas, and the gas supplied to the inner supply tube 210b of the gas supply module 210 is the second cleaning gas.

On the other hand, in FIG. 8, the gas supplied to the inner supply tube 210b of the gas supply module 210 indicates the first cleaning gas, and the gas supplied to the outer supply tube 210a of the gas supply module 210 indicates the second cleaning gas.

In examples of FIGS. 7 and 8, the first cleaning gas is a mixture of argon gas (Ar), nitrogen gas (N₂), and fluorine gas (F₂), and the second cleaning gas is nitric oxide gas (NO).

In the examples of FIGS. 7 and 8, since the ionized first cleaning gas and the non-ionized second cleaning gas are mixed with each other through the plurality of holes 235 of the gas injection module 230 of the gas separation type showerhead 200, the original shape of the nitric oxide gas (NO) included in the second cleaning gas can be maintained to the highest degree.

The order of supplying the first and second cleaning gases to the chamber may be classified into a method of concurrently supplying the first and second cleaning gases to the chamber, a method of firstly supplying the first cleaning gas and then supplying the second cleaning gas to the chamber, and a method of firstly supplying the second cleaning gas and then supplying the first cleaning gas.

Since the first cleaning gas includes fluorine ingredient, it is more effective to concurrently supply the first and second cleaning gases to the chamber or firstly supply the first cleaning gas and then supply the second cleaning gas to the chamber than to firstly supply the second cleaning gas and then supply the first cleaning gas.

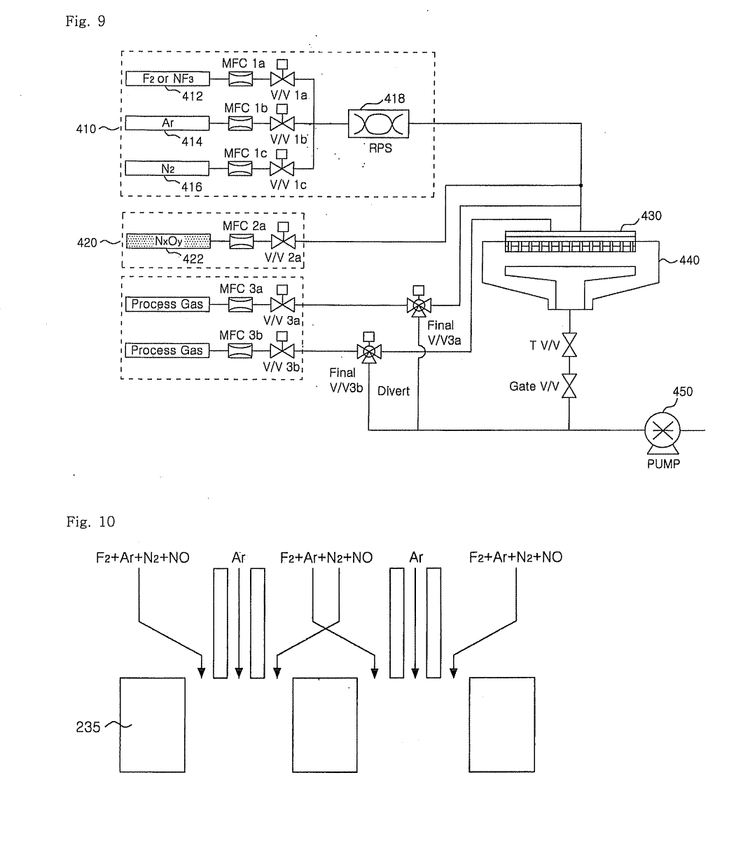

FIG. 9 illustrates another example of a system of supplying a cleaning gas used for the present invention.

Referring to FIG. 9, the first and second cleaning gases may be mixed with each other to form a mixed cleaning gas before being supplied to the gas separation type showerhead 200. In this case, the mixed cleaning gas may be supplied to the outer or inner supply tube 210a or 210b of the gas supply module 210. It is possible to prevent back flow, in which the mixed cleaning gas returns to the gas separation type showerhead 200, by supplying a gas for preventing back flow such as argon gas (Ar) to a supply tube to which the mixed cleaning gas is not supplied.

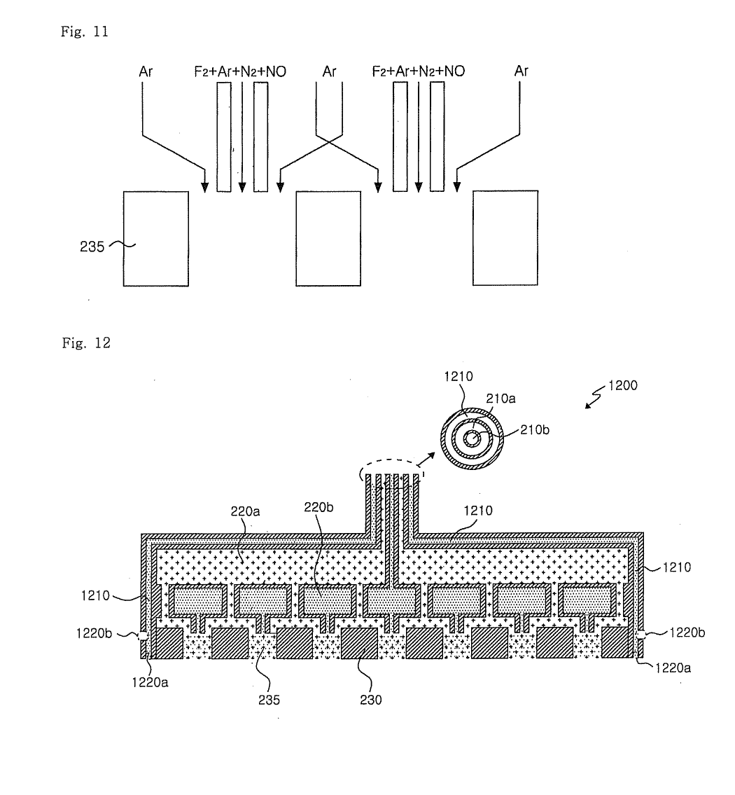

FIGS. 10 and 11 illustrate injection shapes of a mixed cleaning gas and a gas for preventing back flow injected from the gas separation type showerhead 200 shown in FIG. 2.

In FIG. 10, the gas supplied to the outer supply tube 210a of the gas supply module 210 indicates the mixed cleaning gas obtained by mixing the ionized first cleaning gas with the non-ionized second cleaning gas, and the gas supplied to the inner supply tube 210b indicates the gas for preventing back flow.

In FIG. 11, the gas supplied to the inner supply tube 210b of the gas supply module 210 indicates the mixed cleaning gas obtained by mixing the ionized first cleaning gas with the non-ionized second cleaning gas, and the gas supplied to the outer supply tube 210a indicates the gas for preventing back flow.

In examples of FIGS. 10 and 11, the mixed cleaning gas is obtained by mixing the ionized mixture gas of argon gas (Ar), nitrogen gas (N₂), and fluorine gas (F₂) with the non ionized nitric oxide gas (NO), and the gas for preventing back flow is argon gas (Ar).

FIG. 12 illustrates another example of a gas separation type showerhead used for the present invention.

A gas separation type showerhead 1200 shown in FIG. 12 further comprises a third gas supply module 1210 and third gas injection modules 1220a and 1220b in the gas separation type showerhead 200 shown in FIG. 2.

The third gas supply module 1210 surrounds the outer surface of the gas separation type showerhead 200 shown in FIG. 2. A third gas is separated from the first and second gases, supplied and transported through the third gas supply module 1210.

The third gas supplied from the third gas supply module 1210 is injected into the chamber through the third gas injection modules 1220a and 1220b.

The third gas serves to clean the inside of the chamber. Here, the third gas includes a gas containing fluorine (F) ingredient. The third gas may be the ionized first cleaning gas. In addition, the third gas may be a mixed cleaning gas including the ionized first clean gas and the non-ionized second cleaning gas which includes the third gas includes the first cleaning gas and nitrogen oxide based gas (NxOy).

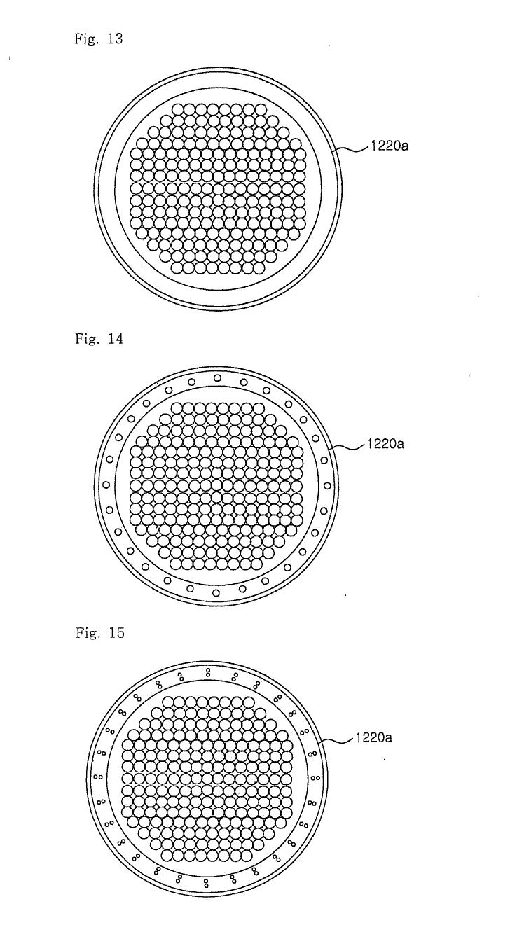

The shapes of the third gas injection modules 1220a and 1220b are various as shown in FIGS. 13 to 17.

FIGS. 13 to 15 are bottom plan views of the third gas injection module 1220a.

FIG. 13 is the bottom plan view of the third gas injection module 1220a with an open structure.

FIG. 14 is the bottom plan view of the third gas injection module 1220a with a hole pattern structure in which a plurality of holes form a single column. In the hole pattern structure, the plurality of holes may form two or more columns. In FIG. 15, there are illustrated a hole pattern structure in which a plurality of holes forms two columns, as an example of the third gas injection module 1220a.

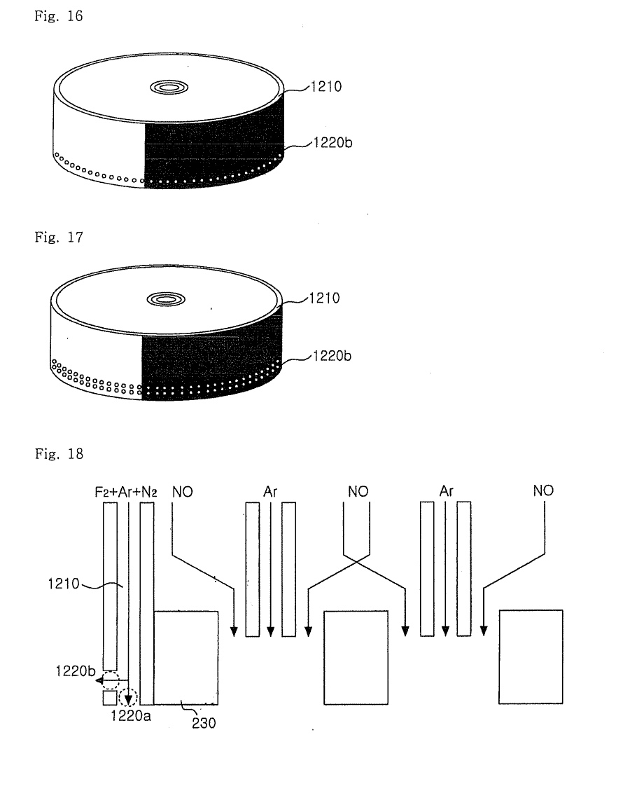

FIGS. 16 and 17 are side views of the third gas injection module 1220b.

FIGS. 16 and 17 are side views of the third gas injection module 1220b with a hole pattern structure in which a plurality of holes form at least one column. Since the third gas injection module 1220b has a structure in which a gas is injected not in the downward direction but in a side direction, it is possible to improve the cleaning efficiency of an upper part of the inside of the chamber.

In FIGS. 13 to 17, injection angles of the plurality of holes which form a hole pattern with respect to the surface onto which the third gas is injected may be irregular or regular. Particularly, in case of a hole pattern in which injection angles of the plurality of holes are irregular, the third gas may be injected in various angles depending on the injection angles of the holes. Therefore, it is possible to effectively clean desiring parts of the inside of the chamber.

In the gas separation type showerhead 1200 shown in FIG. 12, the first and second gases in addition to the third gas may be a gas for cleaning the inside of the chamber.

For example, the first gas may be an ionized first cleaning gas including a gas containing fluorine (F) ingredient, and the second gas may be a non-ionized second cleaning gas including nitrogen oxide based gas (NxOy). At this time, the third gas may be a gas including at least one of the first and second cleaning gases.

For another example, the first gas may be a mixture of the first and second cleaning gases. The second gas may be a gas for preventing back flow, such as argon gas (Ar). At this time, the third gas includes at least one of the first and second cleaning gases.

For still another example, one gas of the first and second gases may be the first or second cleaning gas. The other gas of the first and the second gases may be a gas for preventing back flow. The third gas may be a mixed cleaning gas obtained by mixing the first cleaning gas with the second cleaning gas.

FIGS. 18 to 22 illustrate injection shapes of gases injected from the gas separation type showerhead 1200 shown in FIG. 12.

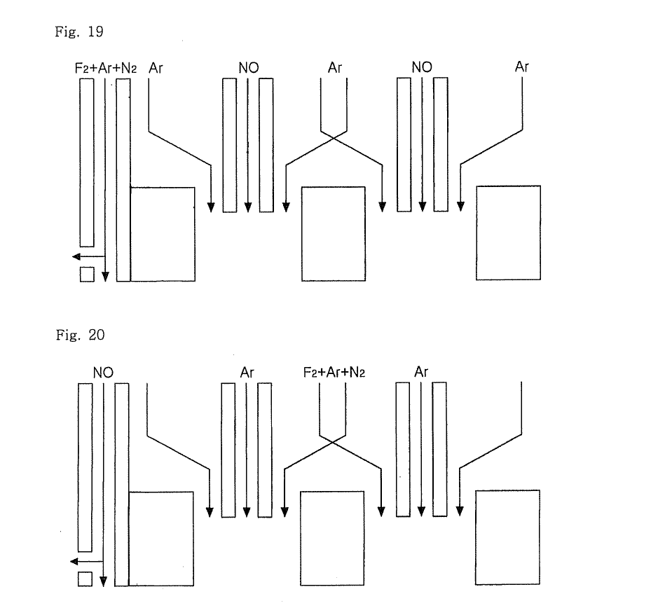

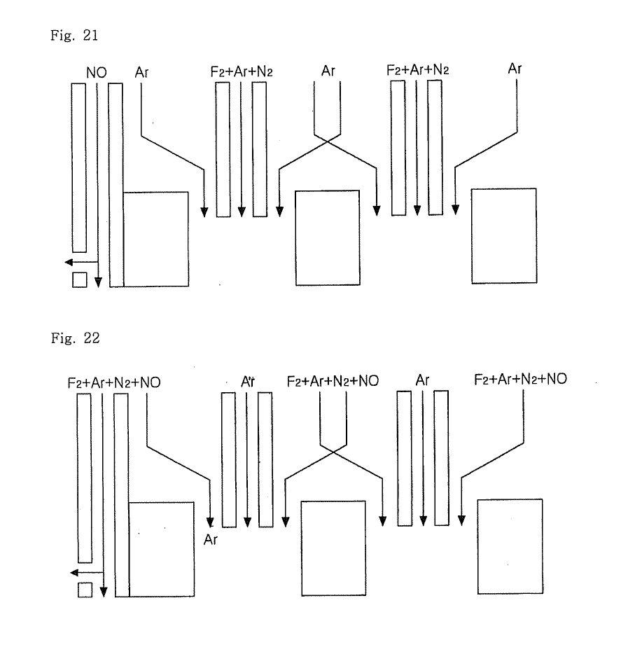

FIG. 18 illustrates an example in which the first gas is the second cleaning gas, the second gas is a gas for preventing back flow, and the third gas is the first cleaning gas. FIG. 19 illustrates an example in which the first gas is a gas for preventing back flow, the second gas is the second cleaning gas, and the third gas is the first cleaning gas. FIG. 20 illustrates an example in which the first gas is the first cleaning gas, the second gas is a gas for preventing back flow, and the third gas is the second cleaning gas. FIG. 21 illustrates an example in which the first gas is a gas for preventing back flow, the second gas is the first cleaning gas, and the third gas is the second cleaning gas. FIG. 22 illustrates an example in which the first gas is a mixed cleaning gas obtained by mixing the first cleaning gas with the second cleaning gas, the second gas is a gas for preventing back flow, and the third gas is a mixed cleaning gas obtained by mixing the first cleaning gas with the second cleaning gas.

In the examples shown in FIGS. 18 to 21, the ionized first cleaning gas is a mixture of argon gas (Ar), nitrogen gas (N₂), and fluorine gas (F₂), the non-ionized second cleaning gas is nitric oxide gas (NO), and the gas for preventing back flow is argon gas (Ar).

As described above, in the apparatus for cleaning a chamber using a gas separation type showerhead, silicon ingredient contained in a solid film is combined with fluorine (F) radicals. Oxygen (O) or nitrogen (N) ingredient which remains in the solid film is excited by the radicals containing fluorine (F) ingredient. The excited oxygen or nitrogen (N) ingredient easily reacts against the nitrogen oxide based gas (NxOy) which is directly supplied without passing through the RPS. Accordingly, there is an advantage that the efficiency of cleaning the inside of the chamber increases.

In addition, in the apparatus for cleaning a chamber using a gas separation type showerhead, it is possible to reduce the time of cleaning the inside of the chamber by additionally supplying the cleaning gas into the chamber through a side of the showerhead to increase the cleaning efficiency of the upper part of the chamber. Accordingly, the amount of the cleaning gas can be reduced, and the productivity is improved.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. An apparatus for cleaning an inside of a chamber using a gas separation type showerhead, the apparatus comprising:
a gas supply module through which first and second gases are separately supplied;
a gas separation module through which the first and second gases are separately dispersed; and
a gas injection module that includes a plurality of holes through which the separately dispersed first and second gases are commonly injected into the chamber,
wherein at least one gas of the first and second gases includes an ionized first cleaning gas including a gas containing fluorine (F) ingredient, and
wherein at least one gas of the first and second gases includes a non-ionized second cleaning gas including nitrogen oxide based gas (NxOy, x and y are integers equal to or more than 1).

2. The apparatus of claim 1,
wherein one gas of the first and second gases is the first cleaning gas, and
wherein the other gas of the first and second gases is the second cleaning gas.

3. The apparatus of claim 1,
wherein one gas of the first and second gases is a mixed cleaning gas obtained by mixing the first cleaning gas with the second cleaning gas, and
wherein the other gas of the first and second gases is a gas for preventing back flow.

4. The apparatus of claim 3, wherein the gas for preventing back flow is argon gas (Ar).

5. The apparatus of claim 1, wherein the first cleaning gas is one selected from the group consisting of i) pure fluorine gas (F₂), ii) a mixture of argon gas (Ar) and fluorine gas (F₂), iii) a mixture of argon gas (Ar), nitrogen gas (N₂), and fluorine gas (F₂), iv) pure nitrogen trifluoride gas (NF₃), and v) a mixture of argon gas (Ar) and nitrogen trifluoride gas (NF₃).

6. The apparatus of claim 1, wherein the second cleaning gas is one selected from the group consisting of i) pure nitrogen oxide based gas and ii) a mixture of argon gas (Ar) and nitrogen oxide based gas (NxOy).

7. The apparatus of claim 1, wherein the gas separation module comprises:
a first dispersion region through which the first gas is dispersed, and is constructed with one region;
a second dispersion region located under the first dispersion region, through which the second gas is dispersed, and is divided into a plurality of regions; and
a plurality of vents disposed under the second dispersion regions, through which the second gas is vented.

8. The apparatus of claim 7, wherein the second dispersion region includes a gas distribution plate for uniformly dispersing the second gas in the plurality of regions.

9. The apparatus of claim 7, wherein the first gas is vented to outer spaces of the plurality of vents from the first dispersion region through outer spaces of the plurality of regions of the second dispersion region.

10. An apparatus for cleaning an inside of a chamber using a gas separation type showerhead, the apparatus comprising:
a gas separation type showerhead including a gas supply module through which first and second gases are separately supplied, a gas separation module through which the supplied first and second gases are separately dispersed, and a gas injection module including a plurality of holes, in which the separately dispersed first and second gases are commonly injected through the plurality of holes;
a third gas supply module surrounding an outer surface of the gas separation type showerhead, through which a third gas for cleaning the inside of the chamber is supplied and transported; and
a third gas injection module through which the supplied third gas is injected into the chamber.

11. The apparatus of claim 10, wherein the third gas injection module has an open structure in the downward direction.

12. The apparatus of claim 10, wherein the third gas injection module has a hole pattern structure in which the plurality of holes form at least one column in the downward direction.

13. The apparatus of claim 12, wherein injection angels of the plurality of holes with respect to a surface onto which the third gas is injected is regular.

14. The apparatus of claim 12, wherein injection angles of the plurality of holes with respect to a surface onto which the third gas is injected is irregular.

15. The apparatus of claim 10, wherein the third gas injection module has a hole pattern structure in which the plurality of holes form at least one column in a side direction.

16. The apparatus of claim 15, wherein injection angles of the plurality of holes with respect to a surface onto which the third gas is injected is regular.

17. The apparatus of claim 15, wherein injection angles of the plurality of holes with respect to a surface onto which the third gas is injected is irregular.

18. The apparatus of claim 10, wherein the third gas is an ionized first cleaning gas including a gas containing fluorine (F) ingredient.

19. The apparatus of claim 18, wherein the first cleaning gas is one selected from the group consisting of i) pure fluorine gas (F₂), ii) a mixture of argon gas (Ar) and fluorine gas (F₂), iii) a mixture of argon gas (Ar), nitrogen gas (N₂), and fluorine gas (F₂), iv) pure nitrogen trifluoride gas (NF₃), and v) a mixture of argon gas (Ar) and nitrogen trifluoride gas (NF₃).

20. The apparatus of claim 10, wherein the third gas is a mixed cleaning gas obtained by mixing the ionized first cleaning gas including the gas containing fluorine (F) ingredient with a non-ionized second cleaning gas including nitrogen oxide based gas (NxOy, x and y are integers equal to or more than 1).

21. The apparatus of claim 20, wherein the first cleaning gas is one selected from the group consisting of i) pure fluorine gas (F₂), ii) a mixture of argon gas (Ar) and fluorine gas (F₂), iii) a mixture of argon gas (Ar), nitrogen gas (N₂), and fluorine gas (F₂), iv) pure nitrogen trifluoride gas (NF₃), and v) a mixture of argon gas (Ar) and nitrogen trifluoride gas (NF₃).

22. The apparatus of claim 20, wherein the second cleaning gas is one selected from the group consisting of i) pure nitrogen oxide based gas and ii) a mixture of argon gas (Ar) and nitrogen oxide based gas (NxOy).

23. An apparatus for cleaning an inside of a chamber using a gas separation type showerhead, the apparatus comprising:
a gas separation type showerhead including a gas supply module through which first and second gases are separately supplied, a gas separation module through which the supplied first and second gases are separately dispersed, and a gas injection module including a plurality of holes, in which the separately dispersed first and second gases are commonly injected through the plurality of holes;
a third gas supply module surrounding an outer surface of the gas separation type showerhead, through which a third gas for cleaning the inside of the chamber is supplied and transported; and
a third gas injection module through which the supplied third gas is injected into the chamber,
wherein at least one gas of the first and second gases and the third gas are gases for cleaning the inside of the chamber.

24. The apparatus of claim 23,
wherein one gas of the first and second gases is an ionized first cleaning gas including a gas containing fluorine (F) ingredient,
wherein the other gas of the first and second gases is a non-ionized second cleaning gas including a nitrogen oxide based gas (NxOy, x and y are integers equal to or more than 1), and
wherein the third gas is a cleaning gas including at least one of the first and second cleaning gases.

25. The apparatus of claim 24, wherein the first cleaning gas is one selected from the group consisting of i) pure fluorine gas (F₂), ii) a mixture of argon gas (Ar) and fluorine gas (F₂), iii) a mixture of argon gas (Ar), nitrogen gas (N₂), and fluorine gas (F₂), iv) pure nitrogen trifluoride gas (NF₃), and v) a mixture of argon gas (Ar) and nitrogen trifluoride gas (NF₃).

26. The apparatus of claim 24, wherein the second cleaning gas is one selected from the group consisting of i) pure nitrogen oxide based gas and ii) a mixture of argon gas (Ar) and nitrogen oxide based gas (NxOy).

27. The apparatus of claim 23,
wherein one gas of the first and second gases is a mixed cleaning gas obtained by mixing the ionized first cleaning gas including the gas containing fluorine (F) ingredient with the non-ionized second cleaning gas including nitrogen oxide based gas (NxOy),
wherein the other gas of the first and second gases is a gas for preventing back flow, and
wherein the third gas is a cleaning gas including at least one of the first and second cleaning gases.

28. The apparatus of claim 27, wherein the first cleaning gas is one selected from the group consisting of i) pure fluorine gas (F₂), ii) a mixture of argon gas (Ar) and fluorine gas (F₂), iii) a mixture of argon gas (Ar), nitrogen gas (N₂), and fluorine gas (F₂), iv) pure nitrogen trifluoride gas (NF₃), and v) a mixture of argon gas (Ar) and nitrogen trifluoride gas (NF₃).

29. The apparatus of claim 27, wherein the second cleaning gas is one selected from the group consisting of i) pure nitrogen oxide based gas and ii) a mixture of argon gas (Ar) and nitrogen oxide based gas (NxOy).

30. The apparatus of claim 27, wherein the gas for preventing back flow is argon gas (Ar).

31. The apparatus of claim 23, wherein the third gas injection module has an open structure in the downward direction.

32. The apparatus of claim 23, wherein the third gas injection module has a hole pattern structure in which the plurality of holes form at least one column in the downward direction.

33. The apparatus of claim 32, wherein injection angels of the plurality of holes with respect to a surface onto which the third gas is injected is regular.

34. The apparatus of claim 32, wherein injection angles of the plurality of holes with respect to a surface onto which the third gas is injected is irregular.

35. The apparatus of claim 23, wherein the third gas injection module has a hole pattern structure in which the plurality of holes form at least one column in a side direction.

36. The apparatus of claim 35, wherein injection angles of the plurality of holes with respect to a surface onto which the third gas is injected is regular.

37. The apparatus of claim 35, wherein injection angles of the plurality of holes with respect to a surface onto which the third gas is injected is irregular.
